(19) United States
(12) Patent Application Publication
(10) Pub. No.: US 2024/0372003 A1
(43) Pub. Date: Nov. 7, 2024

(54) FIELD-EFFECT TRANSISTOR AND METHOD FOR PRODUCING A FIELD-EFFECT TRANSISTOR

(71) Applicant: Robert Bosch GmbH, Stuttgart (DE)

(72) Inventor: Daniel Krebs, Aufhausen (DE)

(21) Appl. No.: 18/649,886

(22) Filed: Apr. 29, 2024

(30) Foreign Application Priority Data
May 3, 2023 (DE) 10 2023 204 065.4

(51) Int. Cl. H01L 29/78; H01L 29/423; H01L 29/66; H01L 29/786

(52) U.S. Cl. CPC H01L 29/7855; H01L 29/4236; H01L 29/66795; H01L 29/78696

(57) ABSTRACT

A field-effect transistor. The field-effect transistor includes: a source layer doped according to a first type, a drain layer doped according to a first type, a channel layer located vertically between the source layer doped according to a first type and the drain layer doped according to a first type, and, extending in particular horizontally, fins and gate trenches, wherein the fins and the gate trenches in each case extend in the vertical direction from the source layer doped according to a first type to the drain layer doped according to a first type, and wherein the gate trenches are in each case formed between two adjacent fins, wherein the field-effect transistor further includes a support structure for the fins.

### FIELD

The present invention relates to a field-effect transistor, in particular to a so-called trench MOSFET, and to a method for producing such a field-effect transistor.

### BACKGROUND INFORMATION

Field-effect transistors (FETs), in particular so-called MOSFETs, are used in various fields. A variant thereof are so-called trench MOSFETs or T-MOSFETs, in which one channel is vertical. In this case, for example, an n-doped source layer and a channel layer located between this source layer and an n-doped drift layer are interrupted by trenches; gate electrodes are then arranged in such trenches.

### SUMMARY

According to the present invention, a field-effect transistor and a method for producing a field-effect transistor are provided. Advantageous example embodiments of the present invention are disclosed herein.

The present invention relates to field-effect transistors, in particular with trenches, and their production. Different types of doping, specifically n-doping and p-doping, are used with semiconductor materials, wherein different components can be doped differently. For the sake of clarity, field-effect transistors are to be described below with a specific type of doping; n-doping is intended to be a doping of a first type, p-doping is intended to be a doping of a second type. However, it is understood that n-doping and p-doping can also be interchanged; i.e., the n-doping could be the second type of doping and the p-doping could be the first type of doping.

A field-effect transistor, for example, has an n-doped source layer and an n-doped drain layer (in particular comprising an n-doped drift layer, for example applied as a so-called epitaxy layer or epitaxial layer). In addition, it has a channel layer located vertically between the n-doped source layer and the n-doped drift layer. The channel layer can be at least partially p-doped. However, for fins smaller than approximately 300 nm it is also possible, for example, that the channel layer is exclusively n-doped. Typically, the n-doped drain layer comprises an n-doped drift layer and an n-doped spread layer which has a higher n-doping than the n-doped drift layer. In this case, the n-doped spread layer is provided vertically between the channel layer and the n-doped drift layer. This n-doped spread layer can, for example, be obtained by suitable doping of a portion of the n-doped drain layer. Furthermore, such a field-effect transistor typically has gate trenches that extend vertically from the n-doped source layer to the n-doped drift layer and are adjoin the channel layer, i.e., in particular also pass through the channel layer.

Furthermore, the field-effect transistor can have gate electrodes, which are at least partially surrounded by a dielectric (for example, a so-called gate oxide), in particular in such a way that the gate electrode is insulated from the n-doped source layer, the channel layer and the n-doped drain layer. One such gate electrode can be arranged in each gate trench. It is also possible that the gate electrode in the gate trench is divided into two, so that each one of the two electrodes created by the division is located in the trench adjacent to one of the two side walls of the gate trench. Between the electrodes, the division makes it possible to lead the source electrode to the bottom of the trench in order to contact a p-shielding doping possibly located below the trenches or some trenches. For example, in each case a projection, a so-called fin, is formed or present between two adjacent gate trenches. This is also referred to as a FinFET or a FinMOSFET.

It is understood that, in addition to the gate electrodes, such a field-effect transistor also has source and drain connections, which can be formed in a conventional manner.

A particular advantage of a trench MOSFET, and therefore also of a FinFET, is that the vertical arrangement makes it possible to arrange many gate electrodes next to one another. The field-effect transistor can in particular be formed as a SiC or GaN field-effect transistor, i.e., a substrate and/or commonly used semiconductor material can be silicon carbide (SiC) or gallium nitride (GaN) since these semiconductor materials have a wide band gap. However, semiconductor materials having an ultra-wide band gap, for example gallium oxide, can also be considered.

With a T-MOSFET and also with a FinFET, the fins and the gate trenches are typically arranged in a cell field. The fins generally extend in parallel with one another and horizontally (i.e., in the plane of extension of the various layers mentioned; in contrast, a vertical direction is to be understood as perpendicular to this plane of extension) in the cell field.

The cell field is usually surrounded by an edge shielding area, which serves to reduce the electric field at the edge in stages rather than abruptly. With a conventional T-MOSFET, only the gate trenches in the cell field are etched during production; the regions between two gate trenches are usually significantly wider than the fins of a FinFET. However, with a FinFET, in particular a power FinMOSFET, all areas except the (usually very narrow) fins in the cell field are etched (i.e., the corresponding material is removed), i.e., the gate trenches along with regions at the edge of the cell field. With the FinFET, this means that the (narrow) fins are free-standing and therefore mechanically unstable, at least before the gate electrodes are introduced.

Within the framework of the present invention, a possibility is now provided to remedy this deficiency by providing a support structure for the fins. Such a support structure can be created, for example, using a suitable mask that represents the fins and the support structure. For example, not only the fins, but also the support structure, remain in place during etching.

In one example embodiment of the present invention, the support structure extends in the vertical direction from the source layer doped according to a first type to the drain layer doped according to a first type. Thus, the height (extension in the vertical direction) of the support structure can correspond to that of the fins.

In one example embodiment of the present invention, the support structure comprises one or more supports (or projections) which in each case connect two fins lying next to one another. Preferably, one or more of the fins are assigned exactly one support in each case. In this way, fewer supports (and therefore a small support structure) are required overall. However, one or more of the fins can also be assigned exactly two supports in each case, which are arranged on different sides of the respective fins (i.e., one extends to an adjacent fin and the other to the other adjacent fin). This enables better stabilization.

In one example embodiment of the present invention, the support structure comprises one or more supports, which in each case is connected to only one of the fins. This enables continuous gate trenches from one end to the other end of the cell field. Preferably, the support structure comprises a plurality of supports grouped as pairs, wherein the supports of a pair are connected in each case to one of the fins on both sides at the same height (viewed in the horizontal direction of extension of the fins). Each of the fins can be assigned a plurality of supports. The support structure can also comprise a plurality of supports, wherein at least two of the plurality of supports are in each case connected to one of the fins on both sides at different heights. This enables stabilization with fewer supports across the direction of extension of the fins.

Such a field-effect transistor can be used alone or together with others, for example as a power switch. Preferred fields of application are, for example, in an electric drive train of a vehicle, for example in a current transformer (DC/DC converter, inverter), in charging devices for electrically powered vehicles or in solar inverters.

Further advantages and embodiments of the present invention can be found in the description and the figures.

The present invention is shown schematically in the figures on the basis of exemplary embodiments and is described below with reference to the figures.

### BRIEF DESCRIPTION OF THE DRAWINGS

FIGS. 1A and 1B schematically show a field-effect transistor to illustrate the present invention.

FIGS. 2A, 2B, and 2C schematically show field-effect transistors according to the present invention in various preferred embodiments.

FIG. 3 schematically shows a sequence of a method according to the present invention in a preferred embodiment.

### DETAILED DESCRIPTION OF EXAMPLE EMBODIMENTS

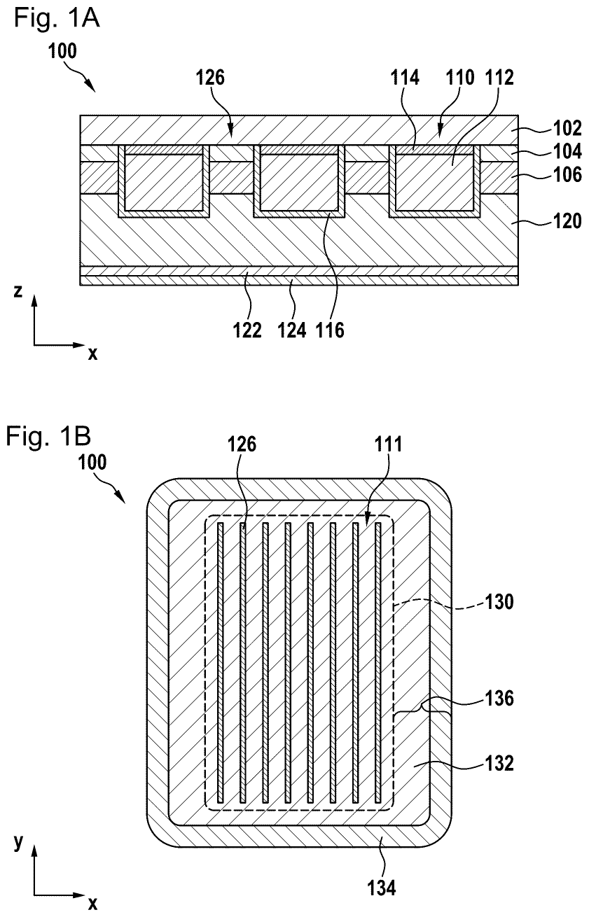

FIGS. 1A and 1B schematically show a field-effect transistor 100 to illustrate the present invention, namely a so-called trench MOSFET as a so-called FinMOSFET. Silicon carbide (SiC), gallium nitride (GaN) or gallium oxide can in particular be used as the semiconductor material since these semiconductor materials have a wide to very wide band gap. FIG. 1A is a sectional view through the complete field-effect transistor 100, while FIG. 1B shows a top view of the incomplete field-effect transistor 100.

As can be seen in FIG. 1A, the field-effect transistor 100 has an n-doped source layer 104, an n-doped drain layer 120 and a channel layer 106 located vertically between the n-doped source layer 104 and the n-doped drain layer 120. The n-doped drain layer 120 can comprise, for example, an n-doped drift layer.

The field-effect transistor 100 has a plurality of gate electrodes 110, which in each case is introduced into one of a plurality of gate trenches (not identified here). The gate trenches extend in the vertical direction (here, the z-direction) from the n-doped source layer 104 to the n-doped drain layer 120 and adjoin the channel layer 106. Between each two of the gate trenches, and therefore also between each two of the gate electrodes 110, there is a projection or a so-called fin 126 in each case.

The gate electrodes 110 each have an insulating oxide 114 and a dielectric or a gate oxide 116 that surrounds a gate semiconductor material 112. The gate electrode (and thus also the associated gate trench) adjoins at least the channel layer 106 via the dielectric 116. The gate electrodes are used to control a channel zone in the channel layer 106. In this case, a region in the channel layer 106 which adjoins the gate electrode or the gate trench forms the channel zone or a channel region.

A gate introduction, i.e. the contacting of the gate electrodes 110 takes place, for example, at the end of a cell field into the drawing plane, in that the material 112 leaves the trench there.

Furthermore, the field-effect transistor 100 has an n-doped substrate 122 adjoining the bottom of the n-doped drain layer 120 and a drain material 124, such as a metal, adjoining the bottom of the n-doped substrate 122. Furthermore, the field-effect transistor 100 has a source material 102, for example a metal, which is adjoins the top of the n-doped source layer 104 and the gate electrodes 110.

FIG. 1B shows a top view of the field-effect transistor 100, but without the introduced gate electrodes and without the source material. In addition to the gate trenches 111, in particular the fins 126 can be seen, which extend in parallel with one another, namely horizontally (i.e., in the plane of extension of the various layers mentioned, here the x-y plane, here by way of example also along the y-direction). The fins 126 and the gate trenches 111 are arranged in a cell field 130.

The cell field 130 is surrounded by an edge shielding area 136, which serves to reduce the electric field at the edge in stages rather than abruptly. Here, for example, stages are shown in two regions 132 and 134, in which, for example, different p-dopings can be provided.

With a FinFET, in particular a power FinMOSFET, all areas except the fins 126 in the cell field are etched (i.e., the corresponding material is removed), i.e., the gate trenches 111 along with regions at the edge of the cell field, for example the region 132. With the FinFET, this means that the narrow fins 126 are free-standing and therefore mechanically unstable, at least before the gate electrodes are introduced. This can be seen in FIG. 1A, for example, if the gate electrodes 110 were not (yet) present there.

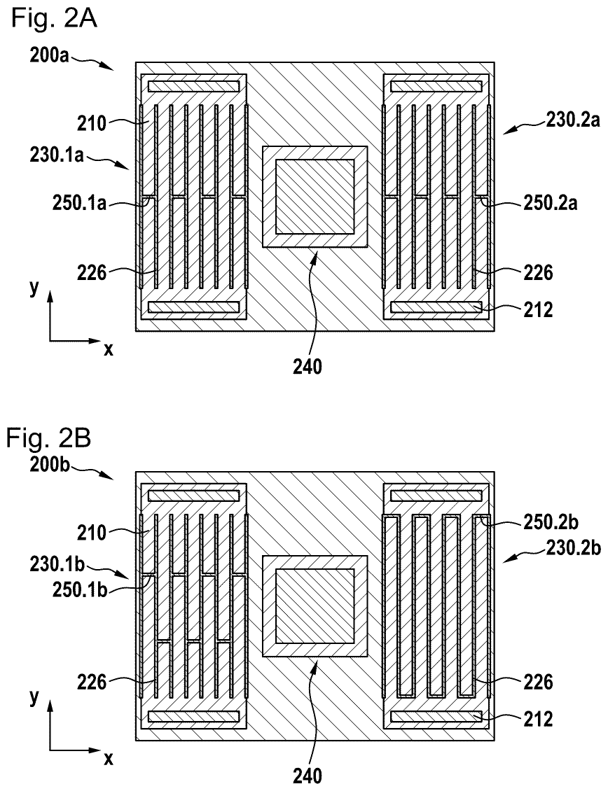

FIGS. 2A, 2B, and 2C schematically show field-effect transistors according to the present invention in various preferred embodiments, namely in a top view comparable to the view in FIG. 1B.

FIG. 2A shows a field-effect transistor 200a with two cell fields 230.1a and 230.2a by way of example. In principle, both cell fields can be constructed in a similar way to the cell field 130 of the field-effect transistor 100, see FIG. 1B. The cell fields 230.1a and 230.2a in each case have fins 126 extending in parallel, and gate electrodes 110 are arranged between two fins 126 in each case. The gate electrodes 110 can be connected at both ends of the respective cell field (viewed in the direction of extension y). In addition, the gate oxide or gate dielectric is open at both ends in each case, so that the semiconductor material 212 can be seen and contacted. Each region of the gate electrodes in each case is connected to at least one such open surface or opening. In addition, the field-effect transistor 200a has a gate pad 240 for contacting, whereby the gate oxide or gate dielectric is also open. In a (complete) field-effect transistor, the fins and gate electrodes are usually covered by metal or power metal, which contacts the gate electrodes at the open regions.

The field-effect transistor 200a has a support structure for the fins 126. In the cell field 230.1a, the support structure comprises, for example, a plurality of supports 250.1a which in each case connect two fins 126 lying next to one another. The supports 250.1a can be designed in the same way as the fins, but while the fins 126 extend along the y-direction, the supports 250.1a extend perpendicularly thereto in the x-direction, but in the same plane of extension, the x-y-plane.

In particular, each fin of the cell field 230.1a is assigned exactly one support 250.1a in each case. In turn, each support 250.1a is assigned to exactly two fins. In other words, two fins are connected to one another via a projection (the support) in each case. This has the advantage that two fins each can stabilize one another via the common projection with a minimal change. Here, by way of example, the supports are arranged in the middle along the direction of extension of the fins, i.e., here along the y-direction, so that the same support effect is generated in the direction of both ends of the cell field.

In the cell field 230.1b, the support structure comprises, for example, a plurality of supports 250.1b which in each case also connect two fins 126 lying next to one another. In particular, however, with the exception of the two outer fins, here each fin of the cell field 230.1b is assigned exactly two supports 250.1b in each case (only one support to the two outer fins in each case). In turn, each support 250.1b is assigned to exactly two fins. In other words, a projection (all supports together) connects all fins and thus stabilizes them. Thus, the individual supports 250.2a are all arranged at the same height in the direction of extension of the fins, here the y-direction.

Therefore, the upper/lower half of the fins, i.e., on the sides of the ends of the cell field, is contacted in each case by the upper/lower gate lead-out. This has the advantage that all fins stabilize one another and not just two fins in each case.

In any case, care must be taken to ensure that the support structures do not create any regions of the gate electrodes that are no longer connected to the openings and are therefore no longer electrically contacted.

FIG. 2B shows a field-effect transistor 200b with two cell fields 230.1b and 230.2b by way of example. The field-effect transistor 200b can correspond to the field-effect transistor 200a; the only difference here is the support structure for the fins.

In the cell field 230.2a, the support structure comprises, by way of example, a plurality of supports 250.2a which in each case also connect two fins 126 lying next to one another. In particular, with the exception of the two outer fins, here exactly two supports 250.2a are assigned to each fin of the cell field 230.2a (only one support to the two outer fins in each case). In turn, each support 250.2a is assigned to exactly two fins. One difference to the cell field 250.2a in FIG. 2A is that the individual supports 250.1b are not all arranged at the same height in the direction of extension of the fins, here the y-direction, but alternately at different heights (but only at two different heights in total, for example). These two heights are, for example, approximately one-third and two-thirds of the length of the fins 126, respectively, always starting from the same end of the fins on one side of the cell field.

In other words, all fins are again connected to one another via a stabilizing projection. However, this is not continuous; rather, two projections or supports in each case are connected to one another in an offset manner. This has the advantage that the length of the fins 126 to the next support is shortened.

In the cell field 230.2b, the support structure comprises, for example, a plurality of supports 250.2b which in each case also connect two fins 126 lying next to one another. In particular, with the exception of the two outer fins, here each fin of the cell field 230.2b is assigned exactly two supports 250.2b in each case (only one support to the two outer fins in each case). In turn, each support 250.2b is assigned to exactly two fins. As with the cell field 250.1b, the individual supports 250.2b are also not all arranged at the same height in the direction of extension of the fins, here the y-direction. In contrast to the cell field 250.1b, these supports 250.2b are arranged alternately in each case at one end and the other end of the fins 126.

In other words, the supports of two fins are arranged in each case at the ends thereof, so that (together with the supports) a meander of fins is created. This has the advantage that the number of corners is reduced and can be completely avoided by rounding off the meander. This is advantageous for processing.

FIG. 2C shows a field-effect transistor 200c with two cell fields 230.1c and 230.2c by way of example. The field-effect transistor 200c can correspond to the field-effect transistor 200a, the only difference being the support structure for the fins.

In particular, each support 250.1c is assigned to exactly one fin 126. Each fin 126, on the other hand, is assigned a plurality of supports in each case. The supports 250.1c are shorter in the x-direction than the supports in FIGS. 2A and 2B, so that the supports do not contact or connect to a second fin. This enables continuous gate trenches from one end to the other end of the cell field, i.e., the gate electrode does not have to be interrupted.

The individual supports 250.1c are arranged here for each fin at different heights in the direction of extension of the fin, here the y-direction, and also in each case alternately on one or the other side of the fin (the sides of the fin are to be understood here in the x-direction). This enables good stabilization.

In the cell field 230.2c, the support structure comprises a plurality of supports 250.2c, for example. Here as well, each support 250.2c is assigned to exactly one fin 126. Each fin 126 is assigned a plurality of supports in each case. The supports 250.2c are shorter in the x-direction than the supports in FIGS. 2A and 2B, so that the supports do not contact or connect to a second fin. This enables continuous gate trenches from one end to the other end of the cell field, i.e., the gate electrode does not have to be interrupted.

In contrast to the cell field 230.1c, pairs of supports 250.2c are formed here, wherein the two supports of a pair of the same height are arranged in each case in the direction of extension of the fin, here the y-direction. By way of example, a plurality of pairs of supports are provided for each fin, wherein the pairs per fin are arranged in each case at different heights in the direction of extension of the fin, here the y-direction. In addition, here by way of example a different number of pairs of supports are provided for the fins, for example alternating between three and two pairs. The pairs of adjacent fins are in turn for example arranged at different heights in the direction of extension of the fins, here the y-direction. This also enables good stabilization.

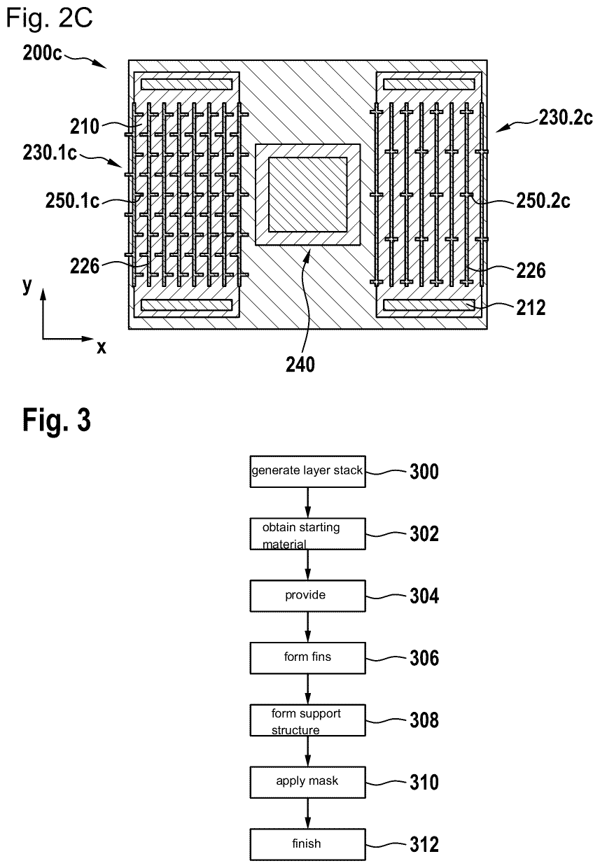

FIG. 3 schematically shows a sequence of a method according to the present invention in a preferred embodiment.

In a step 300, the n-doped source layer 104, the n-doped drain layer 120 and the channel layer 106 located vertically therebetween can first be generated as a layer stack. The starting material 302 thus obtained can then be provided in step 304.

In a step 306, the fins can then be formed as shown in one of FIGS. 2A, 2B, and 2C; here, material for the gate trenches is removed, for example by etching. However, a support structure 308 is also formed together with the fins, as shown in one of FIGS. 2A, 2B, and 2C. This can take place e.g. using a mask 310, which is, for example, applied to the starting material and represents the fins together with the support structure.

In a step 312, the field-effect transistor can then be finished by forming gate oxide, gate semiconductor material, and gate insulation (i.e., introducing the gate electrode) in the trenches or gate trenches, and by contact formation and power metallization.

1-13. (canceled)

14. A field-effect transistor, comprising:
a source layer doped according to a first type;
a drain layer doped according to a first type;
a channel layer located vertically between the source layer doped according to a first type and the drain layer doped according to a first type;
fins and gate trenches extending in particular horizontally wherein each of the fins and the gate trenches extends in a vertical direction from the source layer doped according to a first type to the drain layer doped according to a first type, and wherein the gate trenches are in each case formed between two adjacent fins; and
a support structure for the fins.

15. The field-effect transistor according to claim 14, wherein the support structure extends in the vertical direction from the source layer doped according to a first type to the drain layer doped according to a first type.

16. The field-effect transistor according to claim 14, wherein the support structure includes one or more supports which in each case connect two fins lying next to one another.

17. The field-effect transistor according to claim 16, wherein one or more of the fins are assigned exactly one support in each case.

18. The field-effect transistor according to claim 16, wherein one or more respective fins of the fins are assigned exactly two supports in each case, which are arranged on different sides of the respective fins.

19. The field-effect transistor according to claim 14, wherein the support structure includes one or more supports which in each case are connected to only one of the fins.

20. The field-effect transistor according to claim 19, wherein the support structure includes a plurality of supports grouped as pairs, wherein the supports of each pair are connected in each case to one of the fins on both sides at the same height.

21. The field-effect transistor according to claim 20, wherein each of the fins are assigned a plurality of the supports.

22. The field-effect transistor according to claim 19, wherein the support structure includes a plurality of supports, wherein at least two of the plurality of supports are in each case connected to one of the fins on both sides at different heights.

23. The field-effect transistor according to claim 14, further comprising:
gate electrodes, each of the gate electrodes being at least partially surrounded by a dielectric, in the gate trenches, wherein each region of the gate electrodes is in each case connected to at least one open surface for contacting.

24. The field-effect transistor according to claim 14, wherein the field-effect transistor is a SiC or GaN or gallium-oxide field-effect transistor.

25. A method for producing a field-effect transistor, comprising the following steps:
providing a starting material including: a source layer doped according to a first type, a drain layer doped according a first type and a channel layer located vertically between the source layer doped according to a first type and the drain layer doped according to a first type; and
forming fins in the starting material by removing material at least for gate trenches, which are in each case located between two adjacent fins, wherein a support structure is formed for at least one of the fins.

26. The method according to claim 25, wherein the forming of fins and the support structure is effected using a mask, wherein the mask represents the fins and the support structure.
